(19) United States
(12) Patent Application Publication
(10) Pub. No.: US 2019/0303333 A1
(43) Pub. Date: Oct. 3, 2019

(54) SYSTEM WITH AN INTERPOSER FOR HIGH-SPEED MEMORY MODULES

(71) Applicant: QUALCOMM Incorporated, San Diego, CA (US)

(72) Inventor: Chong DING, Cary, NC (US)

(21) Appl. No.: 15/941,996

(22) Filed: Mar. 30, 2018

(51) Int. Cl. G06F 13/40; H01R 12/73; H05K 1/14; H05K 1/02

(52) U.S. Cl. CPC G06F 13/4027; H01R 12/737; H05K 1/144; H05K 1/0243; H05K 2201/10159; H05K 2201/044; H05K 2201/10189; H05K 2201/10378; H05K 2201/049; H05K 2201/042; H05K 2201/09254; H05K 2201/10325

(57) ABSTRACT

Methods and apparatus for a host to communicate with memory modules via an interposer are presented. An apparatus includes the interposer and a plurality of memory module sockets attached to the interposer. The interposer includes at least one trace electrically connecting a first one of the plurality of memory module sockets and a second one of the plurality of memory module sockets. The at least one trace includes a branching point. A first length of the at least one trace between the branching point and the first one of the plurality of memory module sockets substantially equals to a second length of the at least one trace between the branching point and the second one of the plurality of memory module sockets. The first one of the plurality of memory module sockets communicates with a host via the branching point, a connector, and a circuit board.

### FIELD

The present disclosure relates generally to memory systems, and more particularly, to methods and apparatuses incorporating an interposer for multiple, high-speed memory modules.

### BACKGROUND

Memory is a vital component for modern electronic systems. Memory modules, such as dual-inline memory modules (DIMMs), may be electrically connected to a circuit board via memory module sockets. Examples of the circuit board may include printed circuit boards (PCBs). The memory module socket may be configured to attach to the circuit board and to physically receive (e.g., mate with) a memory module. In such fashion, the memory module may be inserted into the memory module socket and be electrically connected to components on the circuit board. For example, a host may be mounted on or electrically connected to the circuit board and communicate with the memory module via traces on the circuit board and via the memory module socket. Signaling between the host and the memory module may be conducted through the traces on the circuit board and within the memory module socket. Examples of the host may include processors such as central processing units (CPUs) or application processors for mobile applications.

With the ever-increasing demands for more performance, one design challenge is to improve the speed of the signaling between the processor and the memory modules.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

Aspects of an apparatus are presented. The apparatus includes an interposer and a plurality of memory module sockets attached to the interposer. The interposer includes at least one trace electrically connecting a first one of the plurality of memory module sockets and a second one of the plurality of memory module sockets. The at least one trace includes a branching point. A first length of the at least one trace between the branching point and the first one of the plurality of memory module sockets substantially equals to a second length of the at least one trace between the branching point and the second one of the plurality of memory module sockets. The first one of the plurality of memory module sockets communicates with a host via the branching point, a connector, and a circuit board.

Aspects of a method for a host to communicate with memories are presented. The method includes issuing a first command, by a host, to a first one of a plurality of memory modules attached to a first one of a plurality of memory module sockets. The plurality of memory module sockets is attached to an interposer. The method further includes providing the first command to the first one of the plurality of memory modules via a circuit board. A connector is attached to the interposer and to the circuit board, at least one trace on the interposer, and the first one of the plurality of memory module sockets. The at least one trace includes a branching point, and the first command is provided via the branching point to the first one of the plurality of memory module sockets at a first length of the at least one trace. The method further includes issuing a second command, by the host, to a second one of a plurality of memory modules attached to a second one of the plurality of memory module sockets.

Aspects of another apparatus are presented. The apparatus includes an interposer, a plurality of memory module sockets attached to the interposer, a circuit board, and a connector attached to the interposer and the circuit board. The interposer is elevated above the circuit board at least by the connector. The interposer includes at least one trace. A host communicates with one of the memory module sockets via the connector and the at least one trace. The circuit board includes a second trace under the interposer. The second trace is not electrically connected to the plurality of memory module sockets.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1A is a is a diagram of a DIMM and a DIMM socket.

FIG. 1B is a top-view diagram of the DIMM 110.

FIG. 2 is diagram of a circuit board with a host and DIMM sockets.

FIG. 3 is a diagram of signal reflections of DIMMs.

FIG. 4A is a diagram of DIMMs associated with a host via an interposer, in accordance with certain aspects of the disclosure.

FIG. 4B is another diagram of the DIMMs associated with the host via the interposer, in accordance with certain aspects of the disclosure.

FIG. 5 is a diagram of a top view of an interposer and traces thereon, in accordance with certain aspects of the disclosure.

FIG. 6 is a diagram of signal reflections of DIMMs, in accordance with certain aspects of the disclosure.

FIG. 7 is a flowchart for operation of a host communicating with DIMMs.

### DETAILED DESCRIPTION

The detailed description set forth below in connection with the appended drawings is intended as a description of various configurations and is not intended to represent the only configurations in which the concepts described herein may be practiced. The detailed description includes specific details for providing a thorough understanding of various concepts. However, it will be apparent to those skilled in the art that these concepts may be practiced without these specific details. In some instances, well known structures and components are shown in block diagram form to avoid obscuring such concepts.

As used herein, the term “coupled to” in the various tenses of the verb “couple” may mean that element A is directly connected to element B or that other elements may be connected between elements A and B (i.e., that element A is indirectly connected with element B). In the case of electrical components, the term “coupled to” may also be used herein to mean that a wire, trace, or other electrically conductive material is used to electrically connect elements A and B (and any components electrically connected therebetween). In some examples, the term “coupled to” may indicate an electrical current flowing between the elements A and B when referencing electrical components. The term “attached to” in the various tenses of the verb “attach” may mean element A is physically, directly connected to element B in some fashion. For example, the element A may be mounted on, inserted into, or glued or bolted onto the element B.

Several aspects of methods and systems incorporating an interposer for multiple, high-speed memory modules will now be presented. These methods and systems will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the application and design constraints imposed on the overall system. Examples of the systems may include computing systems (e.g., servers, datacenters, desktop computers, Internet of Things devices, etc.) and mobile computing systems (e.g., laptops, cell phones, vehicles, etc.).

With the increasing demands for functions in these systems, more and more electronic components, such as a host and memory modules, are needed within a fixed space on the circuit board. The host may be a device issuing commands to the memory modules to read from or write into the memory modules. The host may provide write data to the memory modules and/or receive read data from the memory modules. Routing traces from (or to) the host on the circuit board to (or from) the memory modules in the limited space, particularly for high speed applications, is becoming increasingly difficult.

Interposers and memory modules presented in the embodiments below may be elevated above the circuit board (e.g., elevated by a connector) to allow for additional space for traces on circuit boards and under the interposers. In such fashion, improved routing of the traces on the circuit boards may allow for high-speed operations of the host accessing the memory modules. Moreover, signal reflections on the interposers may be improved to enhance operating speeds between the host and the memory modules.

The traces on the circuit boards may, for example, include metal or conductive lines on the circuit boards. The memory modules are presented using the non-liming example of dual inline memory modules (DIMM). Memory module sockets are presented using the non-liming example of DIMM sockets. The interposer may, for example, include a circuit boards (e.g., a PCs; note that the interposer may be circuit board different from the circuit board having the host mounted thereon or connected thereto). The connector may, for example, include a mezzanine connector. In some examples, the connector may generally be a connecting apparatus different (e.g., not of the same structure or material) from the interposers and the circuit boards and may be configured to route signaling between the circuit boards and the interposers.

The interposer and other components are presented in the disclosure in reference to an X-axis, a Y-axis, and a Z-axis that are orthogonal to each other. For example, an X-Y plane may be defined by the X-axis and the Y-axis. The X-Y plane may correspond to a horizontal plane, and the Z-axis may be the vertical direction (e.g., elevation) in reference to the X-Y plane.

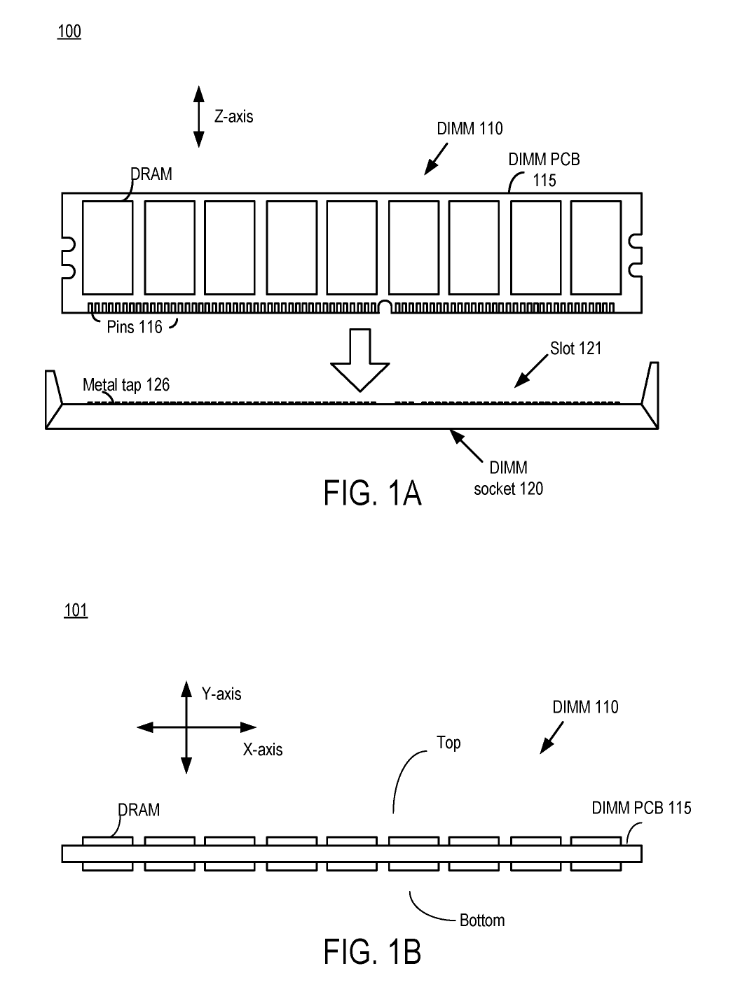

FIG. 1A is a diagram of a DIMM 110 and a DIMM socket 120. The DIMM 110 may be attached to the DIMM socket 120 in the Z-axis direction. In such fashion, the DIMM 110 may be physically and electrically connected to the DIMM socket 120. The DIMM 110 may include a DIMM PCB 115 with memories (e.g., DRAMs) mounted on both sides of the DIMM PCB 115. The sides of the DIMM PCB 115 are referenced as the top and the bottom (see FIG. 1B for further details on the top and the bottom). The top side of the DIMM PCB 115 may have m DRAMs attached thereon, and the bottom side of the DIMM PCB 115 may have n DRAMs (which may differ from the number m) attached thereon. The DIMM 110 further includes pins 116 electrically connected to the DRAMs. The DIMM socket 120 may include a slot 121 to physically receive the DIMM 110. The DIMM socket 120 may further include various metal taps 126 that, with the DIMM 110 is inserted into the DIMM socket 120, electrically and respectively connect to the pins 116 of the DIMM 110.

FIG. 1B is a top-view diagram of the DIMM 110 (e.g., as viewed in the z-axis). The DIMM 110 has two sides, referred to as the top side and the bottom side. As illustrated, each of the top and bottom sides includes nine DRAMs attached thereon (e.g., m equals n in this example).

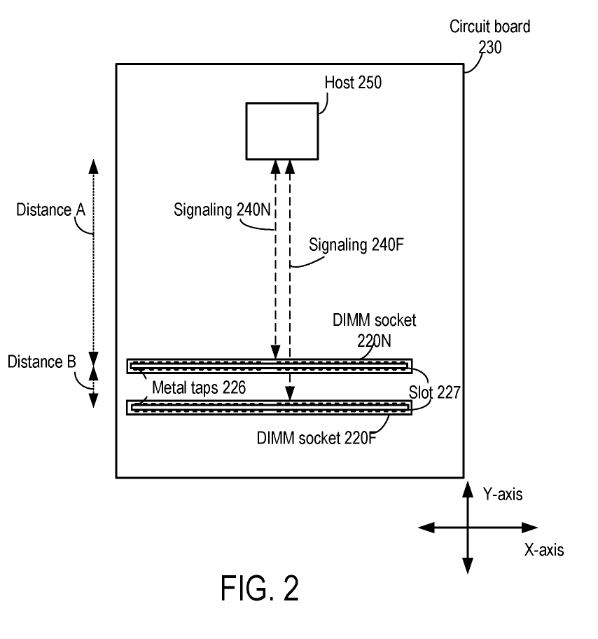

FIG. 2 is diagram of a circuit board 230 with a host and DIMM sockets. The circuit board 230 may be, for example, a motherboard for a personal computer or server, an attachment card such as a video card, or a board for a cell phone or vehicle. The circuit board 230 may include a host 250 (e.g., central processing unit or CPU) and DIMM sockets 220N and 220F (e.g., instances of the DIMM socket 120 of FIG. 1A). Each of the DIMM sockets 220N and 220F includes a slot 227 (instance of the slot 121 of FIG. 1A) to physically receive a DIMM (e.g., DIMM 110 of FIG. 1A). Metal taps 226 (e.g., instances of the metal taps 126 of FIG. 1A) electrically and respectively connect to the pins 116 of the DIMM 110, while the DIMM 110 is mated with the DIMM socket 220N or 220F.

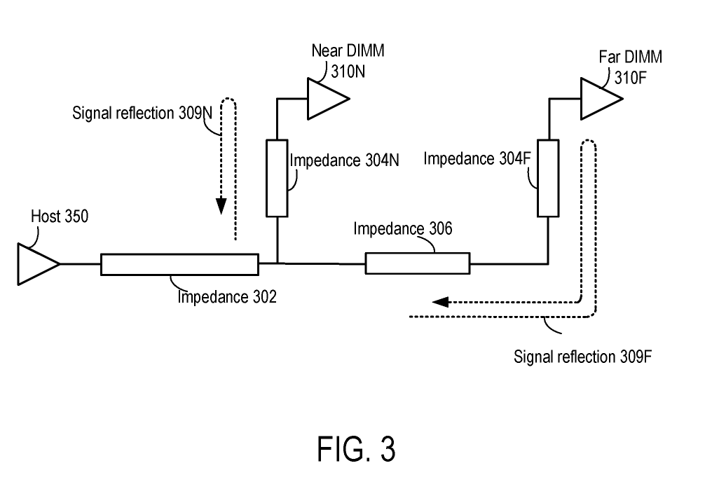

The host 250 may communicate with the DIMM socket 220N via signaling 240N and communicate with the DIMM socket 220F via signaling 240F. The signaling 240N and the signaling 240F may be carried by conductive, connection traces (traces) within the circuit board 230 and may travel different distances. For example, the signaling 240N travels distance A, and the signaling 240F travels distance A and distance B. Signal reflection issues, presented with FIG. 3 below, may arise due to the different distances traveled by the signaling 240N and the signaling 240F. Signal reflections may reduce operating speeds for high-speed applications as communications between the host 250 and the DIMMs (e.g., DIMM 110 of FIG. 1A) need to accommodate the different signal reflections.

FIG. 3 is a diagram of signal reflections of DIMMs. A host 350 (e.g., an instance of the host 250 of FIG. 2) communicates with DIMMs 310N and 310F (e.g., instances of the DIMM 110 of FIG. 1A) via, respectively, the DIMM sockets 220N and 220F of FIG. 2. FIG. 3 illustrates impedances 302, 304N, 304F, and 306. The impedance 302 may correspond to a trace of the length of distance A (see FIG. 2). The impedance 304N may correspond to impedance of the DIMM socket 220N (see FIG. 2), including impedance of traces within a DIMM PCB of the DIMM 310N (e.g., instances of the traces within the DIMM PCB 115 connecting the pins 116 to the DRAMs in FIG. 1A). The impedance 304F may correspond to impedance of the DIMM socket 220F (see FIG. 2), including impedance of traces within a DIMM PCB of the DIMM 310F (e.g., instances of the traces within the DIMM PCB 115 connecting the pins 116 to the DRAMs in FIG. 1A). The impedance 306 may correspond to a trace of the length of distance B (see FIG. 2). The impedance 304N and the impedance 304F may be substantially the same, due to the DIMMs 310N and 310F being a same type of DIMMs (e.g., both the DIMMs 310N and 310F being instances of the DIMM 110 of FIG. 1A).

Signaling between the host 350 and the DIMM 310N and signaling between the host 350 and the DIMM 310F are subject to different signal reflections, due to the different impedances. For example, the signaling between the host 350 and the DIMM 310N passes through the impedance 302 (impedance of a trace of a length of distance A; see FIG. 2) and the impedance 304N. The signaling between the host 350 and the DIMM 310F passes through the impedance 302 (impedance of a trace of a length of distance A; see FIG. 2), the impedance 304F, and, in addition, the impedance 306 (impedance of a trace of a length of distance B; see FIG. 2). As a result, signal reflection 309N (of the signaling between the host 350 and the DIMM 310N) differs from signal reflection 309F (of the signaling between the host 350 and the DIMM 310F). A system illustrated in FIG. 3 generally cannot account for the different signal reflections easily. For example, the host 350 may drive the signaling to the DIMM 310F and the DIMM 310N with the same drive strength. As a result, the signal reflection 309N may suffer from the signal reflection 309F, due the difference in impedances. Signal integrity of the signaling may degrade as a result, limiting the speed to access the DIMMs 310N and 310F.

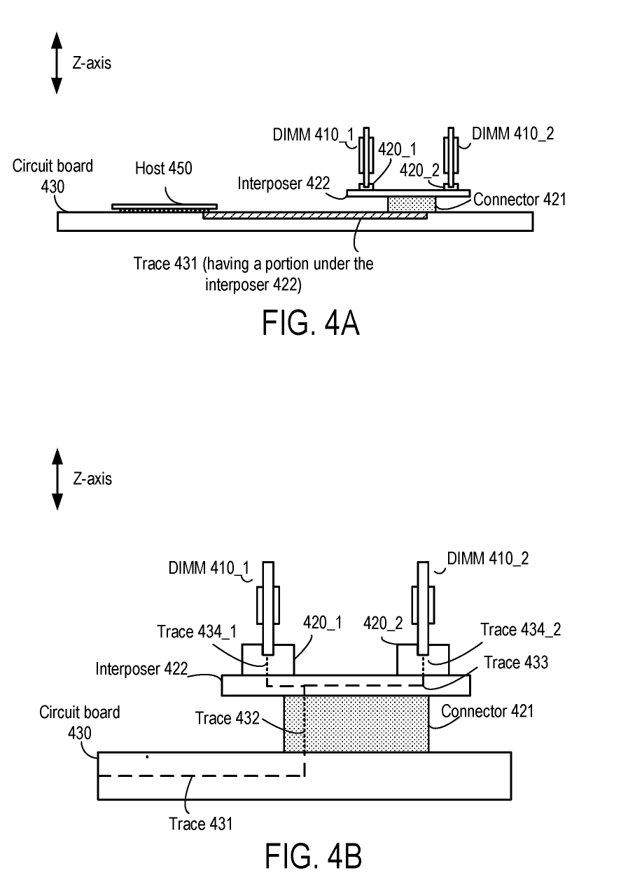

FIG. 4A is a diagram of DIMMs associated with a host via an interposer, in accordance with certain aspects of the disclosure. A circuit board 430 and a host 4350 are illustrated. The host 450 may be an instance of the host 250 (see FIG. 2). The circuit board 430 may be, for example, a PCB. A host 450 is attached and electrically connected to the circuit board 430. The host 450 may be an instance of the host 250 of FIG. 2.

A connector 421 is attached to the circuit board 430. An interposer 422 is attached to (e.g., physically, directly connected to or mounted onto) the connector421. In such fashion, the connector 421 connects (e.g., physical and electrically connects) the interposer 422 and the circuit board 430. In some examples, the connector 421 is a separate structure from the interposer 422 and from the circuit board 430. The connector 421 may elevate the interposer 422 in the Z-axis direction. In some examples, the connector 421 may be a mezzanine connector.

The interposer 422, in some examples, may be a PCB. DIMM sockets 420_1 and 420_2 are attached to the interposer 422. The DIMM sockets 420_1 and 420_2 may be instances of the DIMM socket 120 of FIG. 1. DIMMs 410_1 and 410_2 respectively attach to (e.g., physically, directly connect to or mount onto) the DIMM sockets 420_1 and 420_2. The DIMMs 410_1 and 410_2 may be instances of the DIMM 110 of FIG. 1.

The DIMM sockets 420_1 and 420_2 communicates with the host 450 via the interposer 442, the connector 421, and the circuit board 430. For example, a trace 431 (e.g., at least one) may be routed on a surface of the circuit board 430. The trace 431 may electrically connect the host 450 and the connector 421. A portion of the trace 431 may be under the interposer 422. Examples of the trace 431 may include metal or conductive lines to carry signaling. In such fashion, the DIMMs 410_1 and 410_2 may communicate with the host 450.

FIG. 4B is another diagram of the DIMMs associated with the host via the interposer, in accordance with certain aspects of the disclosure. FIG. 4B includes the trace 431 of the circuit board 430, a trace 432 (e.g., at least one) of the connector 421, a trace 433 (e.g., at least one) of the interposer 422, a trace 434_1 (e.g., at least one) of the DIMM socket 420_1, and a trace 434_2 (e.g., at least one) of the DIMM socket 420_2. The trace 431 of the circuit board 430 may be electrically connected the host 450 (see FIG. 4A) and the trace 432 of the connector 421. The trace 432 of the connector 421 may be electrically connected to the trace 433 of the interposer 422. The trace 433 of the interposer 422 may be electrically connected to the trace 434_1 of the DIMM socket 420_1 and the trace 434_2 of the DIMM socket 420_2. In such fashion, the host 450 may communicate with the DIMMs 410_1 and 410_2 (e.g., issuing read/write commands and write data to the DIMMs 410_1 and 410_2 and receiving read data therefrom) via the circuit board 430, the connector 421, the interposer 422, and the DIMM sockets 420_1 and 420_2.

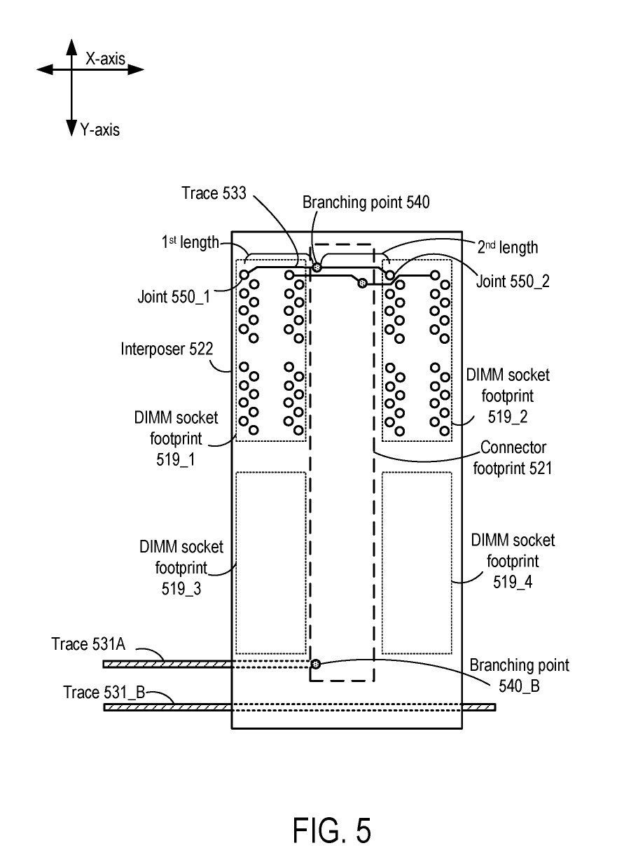

FIG. 5 is a diagram of a top view of an interposer and traces thereon, in accordance with certain aspects of the disclosure. FIG. 5 includes an interposer 522. The interposer 522 may be an instance of the interposer 422 of FIG. 4A. The interposer 522 includes a trace 533, and the trace 533 may be on a surface of or embedded within the interposer 522. The trace 533 may be an instance of the trace 433 of FIG. 4B. The trace 533 includes a branching point 540. The branching point 540 may be electrically connected to the trace 432 of the connector 421, the trace 432, and the host 450 (see FIGS. 4A and 4B). FIG. 5 illustrates that the branching point 540 lies within a connector footprint 521. The connector footprint 521 may indicate the location where the connector 421 (see FIG. 4B) is attached to the interposer 522.

FIG. 5 further illustrates DIMM socket footprints 519_1 and 519_2. The DIMM socket footprints 519_1 and 519_2 may indicate, respectively, the locations where the DIMM sockets 420_1 and 420_2 (see FIG. 4B) are attached to the interposer 522. The interposer 522 further includes joints 550, such as joints 550_1 and 550_2. The joints 550 are electrical connections between the interposer 522 and DIMM sockets. Accordingly, the joints 550_1 and 550_2 may, respectively, be within the DIMM socket footprints 519_1 and 519_2 and may electrically connect to the DIMM sockets 420_1 and 420_2 (FIG. 4B). In such fashion, the branching point 540 may electrically connect to the DIMMs 410_1 and 410_2 (FIG. 4B) respectively attached to the DIMM sockets 420_1 and 420_2 (FIG. 4B) (e.g., electrically connect via the traces 434_1 and 434_2 of FIG. 4B).

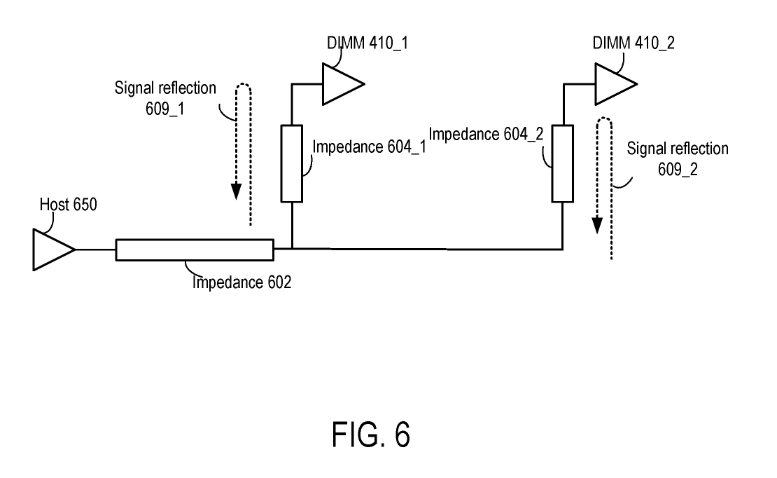

A first length of the trace 533 between the branching point 540 and DIMM socket 420_1 may substantially equal to a second length of the trace 533 between the branching point 540 and the DIMM socket 420_2 (FIG. 4B). In some example, substantially equal may be recognized by persons of ordinary skills in the arts. For example, the first distance and the second distance may be substantially equal for effectively reducing signal reflection variations for high speed operations (e.g., allowing a system incorporating components of FIG. 5 to meet various speed requirements for memory specifications). The signal reflection is presented with further detains in FIG. 6.

In some examples, more than two DIMM sockets may be attached to the interposer 522, and accordingly, more than two DIMMs may be placed on the interposer 522. The interposer 522 includes DIMM socket footprints 519_3 and 519_4 indicating the locations where a third and a fourth DIMM sockets (e.g., in addition to the DIMM sockets 420_1 and 420_2 of FIG. 4B) are attached to the interposer 522.

FIG. 5 further includes traces 531_A and 531_B routed under the elevated interposer 522. The traces 531_A and 531_B may be instances of the trace 431 (FIG. 4A) on a surface of the circuit board 430 (FIG. 4A). Since the interposer 522 is elevated on the Z-axis by the connector 421 (FIG. 4A), traces 531_A and 531_B may be routed under the interposer 522 and under DIMM sockets attached to the interposer 522. The trace 531_A may electrically connect to a branching point 540_B (e.g., an instance of the branching point 540). Thus, the trace 531_A may electrically connect to a DIMM socket attached to the interposer 522 (e.g., the DIMM socket 420_1 of FIG. 4A). The trace 531_B (may be referenced as the second trace for clarity) may pass through under the interposer 522 without electrically connecting to any branching points thereon. Thus, the trace 531_B is not electrically connected to memory module sockets attached to the interposer 522 and not electrically connected to DIMMs attached to the memory module sockets attached to the interposer 522. The additional routing space under the interposer 522 may facility efficient routing of traces on the circuit board 430 (see FIGS. 4A and 4B; e.g., the trace 430 of the FIG. 4A) and improve performance for high-speed operations accordingly.

FIG. 6 is a diagram of signal reflections of DIMMs, in accordance with certain aspects of the disclosure. FIG. 6 includes a host 650 (e.g., an instance of the host 450 of FIG. 4A) communicating with the DIMMs 410_1 and 410_2 (FIGS. 4A and 4B). FIG. 6 includes impedances 602, 604_1, and 604_2. The impedance 602 may correspond to an impedance from the host 630 to a branching point on an interposer (e.g., branching point 540 of the interposer 522 at FIG. 5). For example, the impedance 602 may correspond to impedance of the trace 431 and the trace 432 (FIG. 4B).

The impedance 604_1 may correspond to an impedance from the branching point (e.g., branching point 540 at FIG. 5) to a DIMM (e.g., DIMM 410_1 of FIG. 4B). For example, the impedance 604_1 may correspond to impedance of the trace 533 from the branching point 540 to the joint 550_1 (e.g., at the first distance; see FIG. 5), impedance of the trace 434_1 (FIG. 4B), and impedance within the DIMM 410_1 (FIG. 4B). The impedance 604_2 may correspond to impedance of the trace 533 from the branching point 540 to the joint 550_1 (e.g., at a second distance; see FIG. 5), impedance of the trace 434_2 (FIG. 4B), and impedance within the DIMM 410_2 (FIG. 4B). The first distance and the second distance of the trace 533 are substantially equal (FIG. 5), and the DIMM 410_1 and the DIMM 410_2 are a same type of DIMM (e.g., both may be an instance of the DIMM 110 of FIG. 1A). Accordingly, the impedance 604_1 and 604_2 may be substantially equal.

Accordingly, signaling between the host 650 and the DIMM 410_1 and signaling between the host 650 and the DIMM 410_2 travel through the same or substantially the same impedances. That is, the impedance 602 plus the impedance 604_1 (for the signaling between the host 650 and the DIMM 410_1) and the impedance 602 plus the impedance 604_2 (for the signaling between the host 650 and the DIMM 410_2) are the same or substantially the same as presented above. As a result, signal reflection 609_1 of the signaling between the host 650 and the DIMM 410_1 and signal reflection 609_2 of the signaling between the host 450 and the DIMM 410_2 are the same or substantially the same.

The drive strength of the host 650 may thus be configured to account for the same or substantially the same signal reflections 609_1 and 609_2. As a result, signal integrity of the signaling between the host 650 and the DIMMs 410_1 and 410_2 (FIG. 4B) does not degrade, and the speed of signaling between the host 650 and the DIMMs 410_1 and/or 410_2 may be improved (e.g., operating at a higher frequency).

The apparatuses incorporating the structures illustrated in FIGS. 4A, 4B, and 5 may be one of a computing system (e.g., a server, a desktop, industrial systems, etc.) and a mobile computing system (cell phone, laptop, tablet, vehicle, IOT device, etc.). The apparatus may include an interposer (e.g., the interposer 422 of FIGS. 4A and 4B), a plurality of memory module sockets (e.g., the DIMM sockets 420_1 and 420_2 of FIGS. 4A and 4B) attached to the interposer, a circuit board (e.g., the circuit board 430 of FIGS. 4A and 4B), a connector (e.g., the connector 421 of FIGS. 4A and 4B) attached to the interposer and the circuit board. The interposer may include at least one trace (e.g., the trace 533 of FIGS. 4A and 4B) electrically connecting a first one of the plurality of memory module sockets (e.g., the DIMM socket 420_1 of FIGS. 4A and 4B) and a second one of the plurality of memory module sockets (e.g., the DIMM socket 420_2 of FIGS. 4A and 4B). The at least one trace may include a branching point. For example, referring to FIG. 5, the trace 533 (which may be an instance of the trace 433 of FIGS. 4A and 4B) includes a branching point 540. A first length of the at least one trace between the branching point and the first one of the plurality of memory module sockets substantially equals to a second length of the at least one trace between the branching point and the second one of the plurality of memory module sockets. For example, referring to FIG. 5, the first length of the trace 533 between the branching point 540 and the DIMM socket 420_1 (FIGS. 4A and 4B) substantially equals to the second length of the trace 533 between the branching point 540 and the DIMM socket 420_2. The first one of the plurality of memory module sockets (e.g., DIMM socket 420_1 of FIGS. 4A and 4B) communicates with a host (e.g., the host 450 of FIG. 4A) via the branching point, the connector, and the circuit board.

The interposer may be elevated above the circuit board at least by the connector to allow a second trace (e.g., trace 431 of FIGS. 4A and 4B) on a surface of the circuit board under the interposer. The host communicates with one of the memory module sockets via the connector and the at least one trace. A second trace may be under the interposer and may not electrically connect to the plurality of memory module sockets. For example, referring to FIG. 5, the trace 531_A is not electrically connected to the DIMM sockets 420_1 and 420_2 (FIGS. 4A and 4B). The traces 531_A and 531_B may be instances of the trace 433 (FIGS. 4A and 4B).

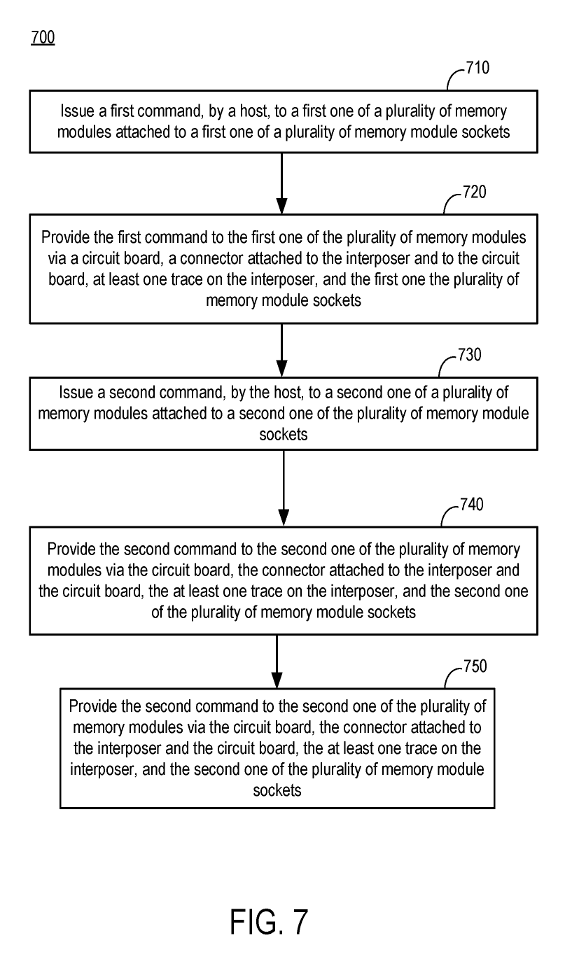

FIG. 7 is a flowchart 700 for operation of a host communicating with DIMMs. The flowchart 700 may be performed by apparatuses/structures described in FIGS. 4A, 4B, and 5. At 710, a first command is issued, by a host, to a first one of a plurality of memory modules attached to a first one of a plurality of memory module sockets. In some examples, the plurality of memory module sockets may be attached to an interposer. As an example, referring to FIGS. 4A and 4B, the DIMM sockets 420_1 and 420_2 are attached to the interposer 422. The host 450 may issue a first command to the DIMM 410_1 attached to the DIMM socket 420_1. The first command may be a read or write command to the DIMM 410_1, for example.

At 720, the first command is provided to the first one of the plurality of memory modules via a circuit board, a connector attached to the interposer and to the circuit board, at least one trace on the interposer, and the first one of the plurality of memory module sockets. As an example, referring to FIGS. 4A and 4B, the read or write command may be provided to the DIMM 410_1 via the circuit board 430, the connector 421 attached to the interposer 422 and the circuit board 430, the trace 431 on the interposer 422, and the DIMM socket 420_1. Referring to FIG. 5, the trace 533 (which may be an instance of the trace 433 of FIGS. 4A and 4B) includes the branching point 540. The first command may be provided via the branching point 540 to the DIMM socket 420_1 (FIGS. 4A and 4B) at the first length of the trace 533.

At 730, a second command is issued, by the host, to a second one of a plurality of memory modules attached to a second one of the plurality of memory module sockets. As an example, referring to FIGS. 4A and 4B, the DIMM sockets 420_1 and 420_2 are attached to the interposer 422. The host 450 may issue a second command to the DIMM 410_2 attached to the DIMM socket 420_2. The second command may be a read or write command, for example.

At 740, the second command is provided to the second one of the plurality of memory modules via the circuit board, the connector attached to the interposer and the circuit board, the at least one trace on the interposer, and the second one of the plurality of memory module sockets. As an example, referring to FIGS. 4A and 4B, the read or write command may be provided to the DIMM 410_2 via the circuit board 430, the connector 421 attached to the interposer 422 and the circuit board 430, the trace 431 on the interposer 422, and the DIMM socket 420_2. Referring to FIG. 5, the trace 533 (which may be an instance of the trace 433 of FIGS. 4A and 4B) includes a branching point 540. The second command may be provided via the branching point 540 to the DIMM socket 420_2 (FIGS. 4A and 4B) at the second length of the trace 533. The first length and the second length may be substantially equal.

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. An apparatus, comprising:
an interposer; and
a plurality of memory module sockets attached to the interposer,
wherein the interposer comprises at least one trace electrically connecting a first one of the plurality of memory module sockets and a second one of the plurality of memory module sockets, the at least one trace comprising a branching point,
wherein a first length of the at least one trace between the branching point and the first one of the plurality of memory module sockets substantially equals to a second length of the at least one trace between the branching point and the second one of the plurality of memory module sockets, and
wherein the first one of the plurality of memory module sockets communicates with a host via the branching point, a connector, and a circuit board.

2. The apparatus of claim 1, further comprising:
the connector, wherein the connector elevates the interposer to allow a second trace on a surface of the circuit board under the interposer.

3. The apparatus of claim 2, wherein the connector comprises a mezzanine connector.

4. The apparatus of claim 2, further comprising the circuit board and the host.

5. The apparatus of claim 4, further comprising a plurality of memory modules respectively attached to the plurality of memory module sockets.

6. The apparatus of claim 5, further comprising one of a computing system and a mobile computing system incorporating the interposer, the plurality of memory module sockets, the connector, the circuit board, the plurality of memory modules, and the host.

7. The apparatus of claim 6, wherein the plurality of memory modules comprises more than two memory modules.

8. A method for a host to communicate with memories, comprising:
issuing a first command, by the host, to a first one of a plurality of memory modules attached to a first one of a plurality of memory module sockets, the plurality of memory module sockets being attached to an interposer;
providing the first command to the first one of the plurality of memory modules via a circuit board, a connector attached to the interposer and to the circuit board, at least one trace on the interposer, and the first one of the plurality of memory module sockets,
wherein the at least one trace comprises a branching point, and the first command is provided via the branching point to the first one of the plurality of memory module sockets at a first length of the at least one trace; and
issuing a second command, by the host, to a second one of a plurality of memory modules attached to a second one of the plurality of memory module sockets.

9. The method of claim 8, comprising:
providing the second command to the second one of the plurality of memory modules via the circuit board, the connector attached to the interposer and the circuit board, the at least one trace on the interposer, and the second one of the plurality of memory module sockets,
wherein the second command is provided via the branching point to the second one of the plurality of memory module sockets at a second length of the at least one trace, the first length and the second length being substantially equal.

10. An apparatus, comprising:
an interposer; and
a plurality of memory module sockets attached to the interposer;
a circuit board;
a connector attached to the interposer and the circuit board,
wherein the interposer is elevated above the circuit board at least by the connector,
wherein the interposer comprises at least one trace,
wherein a host communicates with one of the memory module sockets via the connector and the at least one trace,
wherein the circuit board comprises a second trace under the interposer, and wherein the second trace is not electrically connected to the plurality of memory module sockets.

11. The apparatus of claim 10, wherein the connector comprises a mezzanine connector.

12. The apparatus of claim 10, further comprising the host and a plurality of memory modules respectively attached to the plurality of memory module sockets.

13. The apparatus of claim 12, further comprising one of a computing system and a mobile computing system incorporating the interposer, the plurality of memory module sockets, the connector, the circuit board, the plurality of memory modules, and the host.

14. The apparatus of claim 13, wherein the at least one trace electrically connects the one of the plurality of memory module sockets and a second one of the plurality of memory module sockets,
wherein the at least one trace comprises a branching point, and
wherein a first length of the at least one trace between the branching point and the one of the plurality of memory module sockets substantially equals to a second length of the at least one trace between the branching point and the second one of the plurality of memory module sockets.

15. The apparatus of claim 14, wherein the plurality of memory modules comprises more than two memory modules.
